(19) United States
(12) Patent Application Publication
(10) Pub. No.: US 2006/0172454 A1
(43) Pub. Date: Aug. 3, 2006

(54) Molybdenum alloy

(76) Inventors: Hans-Henning Reis, Bad Klosterlausnitz (DE); Thomas Furche, Altendorf (DE); Klaus Andersson, Kahla (DE)

Correspondence Address: BAYER MATERIAL SCIENCE LLC, 100 BAYER ROAD, PITTSBURGH, PA, 15205, US

(21) Appl. No.: 11/334,221

(22) Filed: Jan. 18, 2006

(30) Foreign Application Priority Data
Jan. 21, 2005 (DE) 102005003445.4

(51) Int. Cl. H01L 21/00; C23C 14/32

(52) U.S. Cl. 438/77; 204/192.1

(57) ABSTRACT

The invention relates to a molybdenum alloy that includes: 94 to 99 weight % of molybdenum; 0.5 to 6 weight % of niobium; and 0.01 to 1 weight % of zirconium. The invention also relates to metal substrates that include such a molybdenum alloy, and anode disks for rotating anode x-ray tubes that include the substrate. Also described are methods of preparing tubular-shaped and disk-shaped molybdenum alloy based sputtering targets.

### CROSS REFERENCE TO RELATED PATENT APPLICATION

The present patent application claims the right of priority under 35 U.S.C. § 119 (a)-(d) of German Patent Application No. 10 2005 003 445.4, filed 21 Jan. 2005.

### FIELD OF THE INVENTION

The invention relates to a molybdenum alloy and its use for metal substrate material for high-temperature applications. In particular, the invention relates to a metal substrate material consisting of molybdenum alloy for the anode disks of rotating anode x-ray tubes for high power requirements, a process for the production of such a material and a process for the production of an anode disk using such a material. The invention furthermore relates to sputtering target consisting of molybdenum alloy and process for producing the sputtering targets.

### BACKGROUND OF THE INVENTION

Anode disks in systems of this type are known to be subject to extreme thermal and mechanical stresses. These parts are therefore made from alloys of the high-melting-point metals tungsten, molybdenum and rhenium. To increase the heat capacity, it is conventional to solder a graphite backing on to the reverse side as heat capacity. The x-ray active layer is produced from a tungsten-rhenium alloy with an extremely high loading capacity.

The manufacture generally takes place by a powder metallurgy route in the following steps: powder preparation, layer compaction, sintering, forging and finishing. More recent developments focus on the application of the x-ray active layer by coating methods.

Of great importance for the functioning of the component is the metal substrate, on one side of which the x-ray active layer and on the other side of which the graphite is applied.

This substrate is normally produced from TZM, which is molybdenum dispersion-alloyed with titanium, zirconium and carbon compounds. These additives block the dislocation motion at the grain boundaries, which on the one hand inhibits the extremely embrittling behaviour known in molybdenum as secondary grain growth as a result of advancing recrystallisation up to temperatures of 1600° C., and at the same time also brings about a significant improvement in the strength properties up to this temperature range.

Similar effects can be achieved by using a substitutional solid solution of molybdenum and tungsten.

Anode disks of molybdenum with additives of niobium produced by powder metallurgy are also known for mammography x-ray tubes.

Dispersion alloys have limited application possibilities. If sufficient thermal energy is introduced into the system, thermodynamic conditions arise to overcome the blockages of the dislocation motion caused by the foreign particles disperse stored at the grain boundaries. Advancing recrystallisation associated with secondary grain growth in particular cases is the unavoidable consequence. Associated with this is a considerable loss of strength, particularly a reduction in the yield point of the material, which clearly exceeds mechanical loads caused by heat. Such processes can be observed in TZM in the temperature range above 1600° C.

In addition to high temperature resistance, vacuum performance and thermal conductivity, the creep properties of the molybdenum alloy and of the substrate material are of great importance for the present application.

As mentioned above, large rotating anode disks can be backed with graphite. Soldering temperatures of up to 1900° C. or more are used for this process, which results in the thermodynamic effects explained above.

In the tube insert, the disk is subject to extreme tangential, and as a result, tensile stresses at rotational speeds of up to 15,000 rotations per minute at base temperatures above 1600° C. Under these conditions, creep processes set in which, while they do not lead to the destruction of the disk in long-term use, do however reach values of more than 0.3%. Although it is only microcreep, this is a value that significantly exceeds the elongation properties of the soldered joint. Separation of the graphite backing occurs, and thus the rotating anode fails and the x-ray tubes are destroyed with high economic loss.

Another aspect is the vacuum performance. The alloying elements introduced in dispersion in TZM are ultimately impurities, which can impair the tube vacuum. The long-term diffusion of carbon in particular to the disk surface can lead to tube failure.

The substitutional solid solution alloy of molybdenum and tungsten brings clear advantages over pure molybdenum. The desired effects can only be observed with relatively high tungsten contents, however. This means on the one hand a marked increase in mass and on the other hand considerable losses of thermal conductivity. Moreover, TZM appears superior to this combination in its action.

The application of the substitutional solid solution of molybdenum and niobium has only been able to find limited acceptance up to now in mammography applications. This can be attributed to the reactivity of niobium towards hydrogen. A hydrogen atmosphere is almost unavoidable when processing molybdenum by powder metallurgy, however. Molybdenum-niobium alloys produced by powder metallurgy overcoming these problems have proved inferior to TZM in terms of their high temperature resistance properties.

In principle, molybdenum alloys with niobium produced in the molten state are known (CH 328 506), but this technical solution is based on a completely different object from the present invention, i.e. to achieve hot-forming properties. This publication also fails to mention zirconium, and niobium is named on an equal standing to vanadium and titanium, which play no part in the present invention.

It is also known to add about 0.02 wt. % of amorphous boron and a multiple of this amount of silicon during the production of molybdenum semi-finished products in the molten state to achieve fine grain structure and ductility (DD 288 509).

The object of the present invention is to provide a molybdenum alloy for high temperature applications, which can advantageously be used as initial material for metal substrate material for the production of anode disks of rotating anode x-ray tubes for high powder requirements and for production of sputtering targets.

### SUMMARY OF THE INVENTION

This object is achieved by a molybdenum alloy that comprises 94 to 99 weight % of molybdenum, 0.5 to 6 weight % of niobium and 0.01 to 1 weight % of zirconium.

Preferably, the molybdenum alloy consist of 95 to 98 weight % molybdenum, 1 to 5 weight % of niobium and 0.04 to 0.5 weight % zirconium, more preferably, of 95 to 97 weight % of molybdenum, 2 to 4 weight % of niobium and 0.05 to 0.2 weight % of zirconium, and most preferably of 95 to 97 weight % of molybdenum, 3 to 4 weight % of niobium and 0.05 to 0.2 weight % of zirconium.

### BRIEF DESCRIPTION OF THE DRAWINGS

FIG. 1 is a representative magnified photomicrograph of a material according to the present invention, after annealing at 1600° C.;

FIG. 2 is a representative magnified photomicrograph of a material according to the present invention, after annealing at a temperature of 1900° C.;

FIG. 3 is a representative schematic sectional view of a consolidated tubular billet; and

FIG. 4 is representative schematic sectional view of the extrusion of a tubular billet.

### DETAILED DESCRIPTION OF THE INVENTION

The molybdenum alloy according to present invention is characterised in that the niobium is predominantly bound with the molybdenum in the substitutional solid solutions. Preferably, more than 95 weight % of the niobium is bound with the molybdenum in the substitutional solid solutions.

According to the present invention, the molybdenum alloy is characterised in that zirconium exhibits dispersion blocking at the grain boundaries.

The molybdenum alloys, according to the present invention, are very pure, as such, have a purity of at least 99.95%, in some cases at least 99.99%, in other cases at least 99.999%.

According to the present invention, the molybdenum alloys are produced by melt metallurgy (pyrometallurgy).

The hardening of the alloy produced in the molten state is substantially attributable to states of microstress, which are produced latently by the difference in the coefficients of thermal expansion between molybdenum and niobium in the optimised composition ranges. Material of the same composition produced by powder metallurgy, on the other hand, is not equivalent.

The molybdenum alloys, according to the present invention are used for the production of high temperature materials for vacuum applications, preferably for the production of metal substrate material for the anode disks of rotating anode x-ray tubes. The advantage of metal substrate material according to the present invention is improving the service life of both x-ray rotating anode disks and thus the x-ray devices fitted with them under increasing thermal and mechanical stresses (higher rotational speed) by improving the material of the metal substrate of these x-ray rotating anode disks. The metal substrate according to the present invention shows improved creep properties.

The creep process of metal substrate measured by DIN EN 1606 reaches value of less than 0.3, preferably less than 0.2, more preferably less than 1.5. In particular cases, metal substrate material shows no creep process.

The present invention therefore provides a metal substrate material consisting of molybdenum alloy.

The present invention provides also a process for the production of metal substrate material in that the melting of the initial compounds, e.g. molybdenum and niobium metal, takes place in a high vacuum.

The cast structure of the high-melting-point metals of subgroups V A and VI A, (vanadium, niobium, tantalum, chromium, molybdenum and tungsten) of the periodic table is known to be very coarse-grained, which can result in insufficient grain-boundary strength in the cast state. This problem is overcome by microalloying with amorphous boron, which is added to the input stock in quantities of no more than 0.02 wt. %, preferably of 0.001 to 0.02 weight %, contributes towards nucleation and deoxidation during the melting process, mostly evaporates during vacuum melting and can normally only be detected qualitatively in the melt product.

It is, of course, impossible to apply the x-ray active layer (focal path) of tungsten-rhenium alloy or other suitable material onto this new substrate material by powder metallurgy. This therefore takes place by a suitable coating method, preferably by vacuum plasma spraying.

Its desired properties relating to high-temperature strength under the particular conditions of use as a substrate material for rotating anode disks in high-power x-ray tubes can be displayed by the new alloy particularly if the grain boundary strength is not decreased by undesirable interstitial impurities on the grain boundary surfaces. The best results are achieved if the production conditions are controlled in such a way that the residual carbon and residual oxygen contents are each guaranteed to be less than 30, and preferably less than 10 ppm by mass.

The molybdenum alloy according to the present invention has the following advantages:

the alloy has high-temperature properties in terms of secondary recrystallisation stability, tensile strength, yield point and elongation equivalent to TZM in the temperature range up to 1700° C.,

in the temperature range above 1800° C., the material is superior to TZM in terms of these properties,

high-temperature annealings above 1800° C. have no substantial effect on microcreep behaviour at high temperatures. The values are significantly below those of TZM in the permissible range for the desired application,

as a result of the lack of impurities, particularly oxygen and carbon, the high-vacuum performance of the material is particularly good,

although the thermal conductivity of the material is somewhat poorer than that of TZM as a result of metal physics, the advantages far outweigh this disadvantage,

the melt-metallurgical technology and the possibility of reprocessing offer clear cost advantages in production and recycling.

The molybdenum-niobium-zirconium material according to the invention is not only suitable as a substrate material for rotating anode disks in high-power x-ray tubes but can also be used for sputtering targets.

In many cases, sputtering targets, particularly those containing molybdenum, have a wrought microstructure with non-uniform grain texture, which may change from one sputtering target to the next. These “non-uniformities” lead to non-uniform films being deposited onto substrates and devices, particularly flat panel displays that do not operate optimally.

In other cases, molybdenum-based sputtering targets are manufactured using a conventional thermomechanical working step. Unfortunately, this methodology generally induces heterogeneity of grain size and texture. The heterogeneity in the sputtering targets typically leads to sputtered films that do not possess the uniformity desired in most semiconductor and photoelectric applications.

The metal substrate material according to the present invention is advantageously used for sputtering targets.

The present invention therefore also provides molybdenum alloy sputtering targets, having fine, uniform grain size as well as uniform texture substantially free of both texture banding and through thickness gradient from a center to an edge of the target with high purity.

As used herein, the term “banding” refers to non-uniformities in the grain or texture, the grain size, or grain orientation that occur in a strip or pattern along the surface of the sputtering target. As used herein, the term “through thickness gradient” refers to changes in grain or texture, grain size, or grain orientation moving from the edge of the target to the center of the target.

The present invention provides a tubular-shaped sputtering target and its method of manufacture. The present method involves the use of molybdenum alloy powder as a starting material, and its consolidation to a substantially fully dense article in the form of a tube. The molybdenum alloy powder is produced by grinding of the molybdenum alloy according to the invention. The tubular form produced has a fine, uniform grain size, and a texture which is substantially uniform throughout, and does not change from tube to tube.

The present invention additionally relates to a method for making a tubular-shaped sputtering target by:

A) placing molybdenum alloy powder in a mold and pressing the powder at a pressure of from 2.200 to 2.760 bar and sintering the pressed piece at a temperature of from 1785 to 2175° C. to form a billet;

B) removing the center of the billet to form a tubular billet having an inner diameter ID₁ and an outer diameter OD₁;

C) working the tubular billet to form a worked billet having an inner diameter ID and an outer diameter OD_{f} such that the ratio of OD₁ to OD_{f} is at least 3:1; and

D) heat treating the tubular billet at a temperature of from 815 to 1375° C.

According to the present invention, a tubular-shaped sputtering target is formed by the pressing and sintering of molybdenum alloy powder to form a billet, removing the center of the billet, working the billet, and heat treating the billet to form a tubular-shaped sputtering target.

Typically, the molybdenum alloy powder is placed in a mold and the powder is pressed at a pressure of at least 1120 bar, in some cases at least 2100 bar and in other cases at least 2200 bar. Also, the powder can be pressed at a pressure of up to 2760 bar, in some cases up to 2.900 bar and in other cases up to 2450 bar. The molybdenum alloy powder in the mold can be pressed at any pressure recited above or at pressures ranging between any of the pressures recited above.

Further, when the pressed billet is sintered in the mold, it is sintered at a temperature of at least 1785° C., in some cases at least 1800° C. and in other cases at least 1850° C. Also, the pressed billet can be sintered at a temperature of up to 2200° C., in some cases up to 2175° C. and in other cases up to 2150° C. The pressed molybdenum billet in the mold can be sintered at any temperature recited above or at temperatures ranging between any of the temperatures recited above.

The pressing of the powders may be performed isostatically. The powder may be sintered in inert gas, e.g., argon or vacuum.

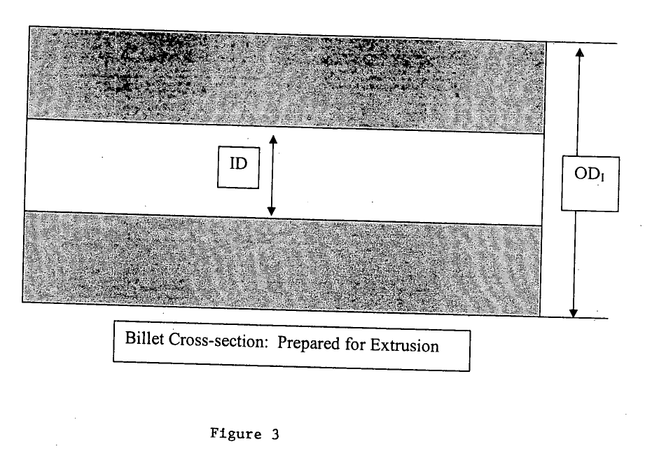

As shown in FIG. 3, the center of the consolidated billet is removed through trepanning such that the ID₁ is smaller than the inside diameter of the finished tubular form. The OD₁ is selected such that the ratio of reduction in cross-sectional area normal to the billet length is at least 3:1, in some cases at least 3.5:1 and in other cases at least 4:1. Also, the reduction in cross-sectional area normal to the billet length can be up to 12:1, in some cases up to 10:1 and in other cases up to 8:1. Preferably, the reduction in cross-sectional area normal to the billet length is 4.9:1 or higher.

The tubular billet is worked to form a worked billet having an inner diameter ID and an outer diameter OD_{f} such that the ratio of OD₁ to OD_{f} is as described above.

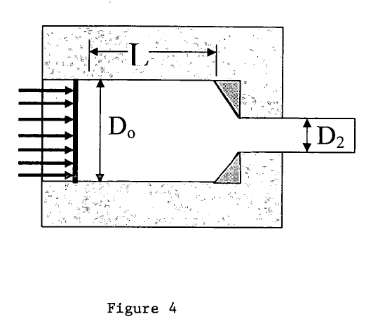

The tubular billet is worked by extruding the billet, as shown in FIG. 4. The billet is extruded with a reduction ratio (created by the change of OD₁ to OD_{f}) in cross-sectional area as described above. The billet length may be variable. The product form ID is controlled through the use of mandrel tooling.

The tubular billet can be extruded at a temperature of at least 925° C., in some cases at least 950° C., and in other cases at least 1000° C. Also, the tubular billet can be extruded at a temperature of up to 1370° C., in some cases up to 1260° C. and in other cases up to 1175° C. The tubular billet can be extruded at any temperature recited above or at a temperature ranging between any of the temperatures recited above.

After working the billet, it is heat treated at a temperature of at least 815° C., in some instances at least 925° C., in some cases at least 950° C. and in other cases at least 1000° C. Also, the heat treatment can be carried out at up to 1375° C., in some cases up to 1260° C. and in other cases up to 1175° C. The heat treatment can be at any temperature or range between any temperatures recited above.

In a particular embodiment of the invention, the heat treatment is carried out at temperatures from 1250 to 1375° C.

In another particular embodiment of the invention, the heat treatment is carried out at temperatures from 815 to 960° C.

A particular advantage of the present tubular-shaped sputtering target is its uniform texture. The sputtering target is completely recrystallized and strain-free.

There is no banding of texture at all. The fine, uniform grain size, and the uniformity of texture through the thickness of the tube and along the length of the tube are features which distinguish the present invention from the prior art. These features allow for more uniform film deposition during sputtering operations.

Thus, the present invention provides a sputtering target having a uniform and fine texture and grain structure. In an embodiment of the invention, the grain size is at least 22 μm, and in some cases at least 45 μm. More importantly, however, the average grain size is not more than 125 μm, in some cases not more than 90 μm and in other cases not more than 65 μm.

The present invention provides also a disc-shaped sputtering targets and its method of manufacture.

Embodiments of the invention are also directed to a novel method of manufacturing of disc-shaped sputtering targets, which produces performance superior to that which is presently known in the art. This method of manufacture involves the use of molybdenum alloy powder as a starting material and its consolidation to a substantially fully dense article in the form of a plate. The inventive plate, which is produced through a multi-directional thermomechanical working process as described below, has a fine, uniform grain size and a texture which is substantially uniform throughout the plate.

In an embodiment of the invention, the plates have a texture that is substantially free of banding and substantially free of any through thickness gradient. Thus, in a first step A), the molybdenum alloy powder is placed in a mold and pressed at a pressure of at least 1000 bar, in some cases at least 2000 bar and in other cases at least 2500 bar. Also, the powder can be pressed at a pressure of up to 2750 bar. The molybdenum alloy powder in the mold can be pressed at any pressure recited above or at pressures ranging between any of the pressures recited above.

Further, after the molybdenum alloy powder is pressed in the mold, it is sintered at a temperature of at least 1785° C. Also, the powder can be sintered at a temperature of up to 2175° C., in some cases up to 2200° C. The pressed molybdenum alloy workpiece can be sintered at any temperature recited above or at temperatures ranging between any of the temperatures recited above.

In an embodiment of the invention, the pressing is performed isostatically. In another embodiment of the invention, the pressed powder is sintered in inert gas or vacuum. Thus, the molybdenum alloy metal powder can be placed in a rubber mold, isostatically pressed and the pressed piece then sintered in hydrogen to form a billet with a cross-sectional area which can be from 1.5 to 4, in some cases from 2 to 3, and in a particular embodiment approximately 2.4 times the size of the intended target cross-sectional area of the eventual sputtering target. In other words, the billet has a diameter of Dₒ.

The billet is then preheated, prior to extruding, to a temperature of at least 900° C., in some cases 925° C. and in other cases at least 950° C. Also, the billet can be preheated to a temperature of up to 1260° C., in some cases 1225° C. and in other cases up to 1175° C. The preheated temperature can be any value or can range between any values recited above.

As shown in FIG. 4, the billet is extruded to form an extruded billet having a diameter of D₂, such that the ratio of reduction (Dₒ:D₂) in cross-sectional area is at least 2.5:1, in some cases at least 3:1 and in other cases at least 3.5:1. Also, the ratio of reduction can be up to 12:1, in some cases 10:1 and in other cases up to 8:1. The ratio of reduction can be any value or range between any values recited above. The billet length can be variable.

In order to prepare the extruded billet for upset forging, it is subjected to a first heat treatment step. This heat treatment step generally provides stress relief. The first heat treatment is conducted at a temperature of at least 800° C., in some cases at least 815° C., in some cases at least 830° C. and in other cases at a temperature of at least 850° C. Also, the first heat treatment can be conducted at a temperature up to 960° C., in some cases up to 930° C. and in other cases up to 900° C. The temperature of the first heat treatment step can be any value recited above or can range between any values recited above.

In an embodiment of the invention, the billet is cut to a length such that the billet's aspect ratio (Length/Diameter) is less than or equal to 2.0, in some cases less than or equal to 1.6.

After the first heat treatment and before upset forging, the heat-treated extruded billet is preheated to a temperature of at least 900° C., in some cases at least 925° C., in other cases at least 950° C., in some situations at least 975° C. and in other cases at least 1000° C. Also, the heat-treated extruded billet can be preheated to a temperature of up to 1300° C., in some cases up to 1260° C., in other cases up to 1200° C. and in some instances up to 1150° C. Prior to upset forging, the heat-treated extruded billet can be preheated to any temperature recited above or can range between any temperature recited above.

The upset forging of the extruded billet is carried out at a temperature of at least 800° C., in some cases at least 900° C., in other cases at least 925° C. and in some instances at least 950° C. Also, the upset forging of the extruded billet can be carried out at up to 1300° C., in some cases up to 1260° C., in other cases up to 1200° C., in some instances up to 1100° C. and in other instances up to 1000° C. The forging temperature allows the billet to be forged to form a forged billet having a diameter D_{f} as described above. The forging temperature can be any temperature described above or can range between any of the temperatures recited above.

After forging, the forged billet is subjected to a second heat treatment step. The second heat treatment step is a recrystallization step that provides a strain-free equiaxial grain structure. The second heat treatment is conducted at a temperature of at least 1200° C., in some cases at least 1250° C., in some cases at least 1275° C. and in other cases at a temperature of at least 1300° C. Also, the second heat treatment can be conducted at a temperature up to 1400° C., in some cases up to 1375° C. and in other cases up to 1350° C. The temperature of the second heat treatment step can be any value recited above or can range between any values recited above.

As indicated above, the second heat treatment is applied at a temperature and for a time that provides a billet that has a strain-free equiaxial grain structure. Thus, after the second heat treatment, a billet is provided that is completely recrystallized and strain free.

The material affected during upset forging by the centering disks (CD) is removed. The material affected by the centering disks is not generally usable as target material. Sputtering targets are sliced from the billet. The entirety of the billet is usable as target once the centering disk affected material is removed.

In an embodiment of the present invention, a sputtering target is provided having a uniform and fine texture and grain structure. In an embodiment of the invention, the grain size is at least 22 μm and in some cases at least 65 μm. More importantly, however, the average grain size is not more than 125 μm, in some cases not more than 90 μm and in other cases not more than 65 μm as determined by electron backscatter diffraction. When the grain size is too large and/or non-uniform, thin films formed from sputtering the present sputtering target will not have the desired uniform texture and/or film thickness. The grain size in the present sputtering target can be any value or range between any values recited above.

Additionally, the present invention provides a method of sputtering, whereby any of the above-described sputtering targets are subjected to sputtering conditions and are thereby sputtered.

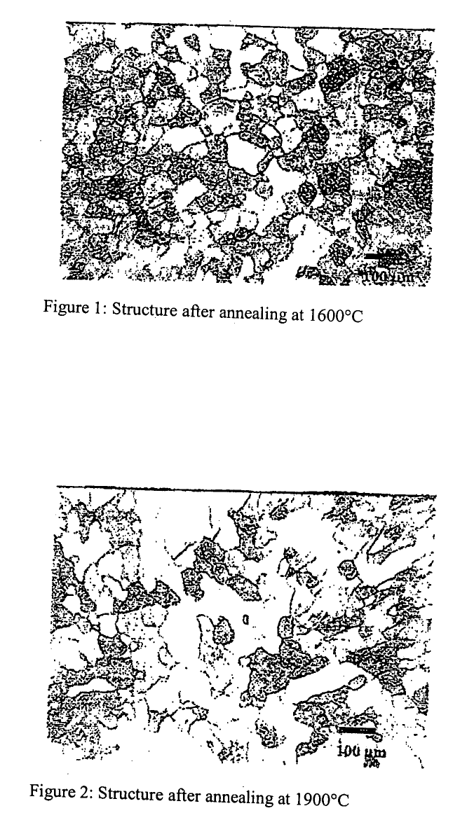

Any suitable sputtering method can be used in the present invention. Suitable sputtering methods include, but are not limited to, magnetron sputtering, pulse laser sputtering, ion beam sputtering, triode sputtering, and combinations thereof. The invention is described below in more detail on the basis of an example. FIGS. 1 and 2 are showing enlarged structural photographs of a material according to the invention after treatment by annealing at different temperatures. The quasi-homogeneous structure of the molybdenum-niobium-zirconium solid solutions becomes clear. Even high-temperature treatments—as can be seen—do not result in any secondary grain growth. Thus, the action of the solution according to the invention is documented. The individual elements can be detected qualitatively and quantitatively by suitable methods.

The present invention provides a molybdenum-niobium-zirconium-alloy for high-temperature applications in vacuum.

In an embodiment of the invention the starting materials, molybdenum, niobium and zirconium (input stock), is melted in an electron—beam furnace to obtain an ingot. In order to avoid the oxidation during the electron-beam melting up to 300 ppm, preferably up to 200 ppm, particularly preferably up to 100 ppm boron are added to the input stock. The resulting ingot is then processed by suitable forming processes, such as extruding, rod-extrusion, forging and heat treatment (annealing). The heat treatment is carried out at from 1300 to 1500° C., preferably at 1350 to 1450° C., particularly preferably at 1380 to 1400° C. After the forming and heat treatment the semi-finished product is processed into substrates for high-temperature applications by forming processes such as forging, rolling or milling.

If the substrate material is to become rotating anode disc, a x-ray active layer is to be applied to the surface thereof. This can be done by conventional methods, such as, but not limited to, vacuum plasma spraying or inductive vacuum plasma spraying. The x-ray active layer may consists of any materials suitable therefore and in general is a tungsten-rhenium layer.

The resulting parts are processed into rotating anode disks by conventional methods, e.g. drilling, milling, turning or grinding.

In a specific embodiment, the part is processed to a rotating anode disc by a process comprising the steps of

1) turning

2) milling

3) drilling and

4) grinding.

After working the disks, the heat treatment is carried out to achieve a uniform, completely recrystallised structure illustrated by light microscopy in FIG. 1. The heat treatment is carried out at from 1400 to 1800° C., preferably from 1500 to 1700° C., particularly preferably from 1550 to 1650° C., very particularly preferably 1550 to 1600° C. The following heat treatment of the anode disks at from 1800 to 2000° C., preferably from 1850 to 1950° C., results in structure which is characterized by complete molybdenum-niobium solid solution formation, FIG. 2.

The metal substrate material according to the present invention shows the relatively uniform and completely recrystallised structure. The structure is uniform if a distribution of grain sizes that vary by less than 30 percent across the surface of any plane of said substrate material, said planes being selected from planes that are orthogonal to the thickness of said substrate material, and planes that are diagonal to the thickness of said substrate material, and a distribution of grain sizes that vary by less than 30 percent across any thickness of said substrate material.

The invention is illustrated in further detail below by reference to examples, wherein the examples are intended to simplify understanding of the principle according to the invention and should not be understood as a limitation thereof.

### EXAMPLES

### Example 1

96.5 kg molybdenum, 3.45 kg niobium and 0.05 kg zirconium are prepared as the input stock,

100 ppm by mass of boron are added to this inputstock,

the feedstock is melted in an electron-beam furnace,

the resulting ingot is processed by extruding and annealing at 1350° C.,

the semi-finished product is processed into substrates for rotating anode disks by forging and annealing at 1500° C.,

a tungsten-rhenium layer is applied on to these substrates by means of a vacuum plasma spraying process,

the resulting parts are processed into rotating anode disks by sequential steps:

1) turning

2) milling

3) drilling and

4) grinding,

following a heat treatment at 1600° C. for 2 hours, the substrates of the rotating anode disks are characterised by the relatively uniform, completely recrystallised structure illustrated by light microscopy in the attached FIG. 1, with the average grain size stated,

following heat treatment at 1900° C. for 1 hour,

the structure of the substrate is characterised by complete molybdenum-niobium solid solution formation,

zirconium and boron can be detected relatively uniformly in the substrate structure,

the residual carbon content is less than 10 ppm by mass,

the residual oxygen content is less than 10 ppm by mass.

### Example 2

97.5 kg molybdenum, 2.45 kg niobium and 0.05 kg zirconium are prepared as the input stock,

the feedstock is melted in an electron-beam furnace,

the resulting ingot is processed by extruding and annealing at 1450° C.,

the semi-finished product is processed into substrates for rotating anode disks by forging and annealing at 1450° C.,

a tungsten-rhenium layer is applied on to these substrates by means of a vacuum plasma spraying process,

the resulting parts are processed into rotating anode disks by sequential steps:

1) turning

2) milling

3) drilling and

4) grinding,

following a heat treatment at 1550° C. for 2 hours, the substrates of the rotating anode disks are characterised by the relatively uniform and completely recrystallised structure,

following heat treatment at 1850° C. for 1 hour,

the structure of the substrate is characterised by complete molybdenum-niobium solid solution formation,

zirconium can be detected relatively uniformly in the substrate structure,

the residual carbon content is less than 10 ppm by mass,

the residual oxygen content is less than 30 ppm by mass.

### Example 3

96.99 kg molybdenum, 3.0 kg niobium and 0.01 kg zirconium are prepared as the input stock,

50 ppm by mass of boron are added to this input stock,

the feedstock is melted in an electron-bombardment furnace,

the resulting ingot is processed by extruding and annealing at 1350° C.,

the semi-finished product is processed into substrates for rotating anode disks by forging and annealing at 1500° C.,

a tungsten-rhenium layer is applied on to these substrates by means of a vacuum plasma spraying process,

the resulting parts are processed into rotating anode disks by sequential steps:

1) turning

2) milling

3) drilling and

4) grinding,

following a heat treatment at 1650° C. for 2 hours, the substrates of the rotating anode disks are characterised by the relatively uniform, completely recrystallised structure,

following heat treatment at 1950° C. for 1 hour,

the structure of the substrate is characterised by complete molybdenum-niobium solid solution formation,

zirconium and boron can be detected relatively uniformly in the substrate structure,

the residual carbon content is less than 10 ppm by mass, the residual oxygen content is less than 15 ppm by mass.

Although the invention has been described in detail in the foregoing for the purpose of illustration, it is to be understood that such detail is solely for that purpose and that variations can be made therein by those skilled in the art without departing from the spirit and scope of the invention except as it may be limited by the claims.

What is claimed is:

1. A molybdenum alloy comprising:
94 to 99 weight % of molybdenum,
0.5 to 6 weight % of niobium, and
0.01 to 1 weight % of zirconium.

2. The molybdenum alloy of claim 1 wherein the niobium is predominantly bound with the molybdenum in a substitutional solid solution.

3. The molybdenum alloy of claim 1 wherein more than 95 weight % of the niobium is bound with the molybdenum in a substitutional solid solution.

4. The molybdenum alloy of claim 1 wherein zirconium exhibits dispersion blocking at grain boundaries.

5. The molybdenum alloy of claim 1 wherein said molybdenum alloy has a purity of at least 99.95%.

6. The molybdenum alloy of claim 1 wherein the molybdenum alloy is produced by melt metallurgy.

7. A method comprising:
providing the molybdenum alloy of claim 1; and
forming a high temperature material for vacuum applications comprising the molybdenum alloy.

8. A metal substrate material comprising a molybdenum alloy comprising,
94 to 99 weight % of molybdenum,
0.5 to 6 weight % of niobium, and
0.01 to 1 weight % of zirconium.

9. A process for producing the metal substrate of claim 8 comprising melting a composition comprising said molybdenum alloy under conditions of high vacuum.

10. The process of claim 9 wherein said composition further comprises 0.001 to 0.02 weight % of amorphous boron.

11. The process of claim 9 wherein said metal substrate is uniformly recrystallised by a method selected from the group consisting of annealing said metal substrate, forming said metal substrate and combinations thereof.

12. The process of claim 9 wherein process conditions are controlled during all the phases of the process in such a way that said metal substrate has a residual carbon content of less than 30 ppm by mass, and a residual oxygen content of less than 30 ppm by mass.

13. An anode disk for a rotating anode x-ray tube comprising the metal substrate of claim 8.

14. A process for producing an anode disk for a rotating anode x-ray tube, comprising applying an x-ray active layer to a metal substrate comprising a molybdenum alloy comprising,
94 to 99 weight % of molybdenum,
0.5 to 6 weight % of niobium, and
0.01 to 1 weight % of zirconium,
wherein said x-ray active layer is applied to said metal substrate by a method selected from the group consisting of vacuum plasma spraying and inductive vacuum plasma spraying.

15. The process of claim 14 wherein said x-ray active layer comprises of a tungsten-rhenium alloy.

16. A sputtering target comprising the metal substrate material of claim 8.

17. The sputtering target of claim 16 wherein said sputtering target has high purity, fine uniform grain size, and uniform texture substantially free of both texture banding and through thickness gradient from a center to an edge of the sputtering target.

18. The sputtering target of claim 17 wherein the fine uniform grain size is less than or equal to 125 μm.

19. The sputtering target of claim 17 wherein said sputtering target has a shape selected from group consisting of tubular shapes, round shapes, square shapes and rectangular shapes.

20. A method of producing a tubular-shaped sputtering target comprising:
(A) (i) placing a molybdenum alloy powder composition in a mold,
(ii) pressing said molybdenum alloy powder composition at a pressure of 2.200 to 2.760 bar, thereby forming a pressed piece, and
(iii) sintering said pressed piece at a temperature of 1785 to 2175° C. to form a billet;
(B) removing the center of said billet to form an initial tubular billet having an inner diameter ID₁ and an outer diameter OD₁;
(C) working said initial tubular billet to form a worked tubular billet having an inner diameter ID and an outer diameter OD_{f} such that the ratio of OD₁ to OD_{f} is at least 3:1; and
(D) heat treating the worked tubular billet at a temperature of 815 to 1375° C., thereby forming said tubular-shaped sputtering target.

21. The method of claim 20 wherein pressing step (A)(ii) is performed isostatically.

22. The method of claim 20 wherein sintering step (A)(iii) is conducted in the presence of an inert gas or under a vacuum.

23. The method of claim 20 wherein ID is greater than ID₁.

24. The method of claim 20 wherein working step (C) comprises extruding the initial tubular billet at a temperature of 925 to 1260° C.

25. The method of claim 20 wherein working step (C) comprises rotary forging the initial tubular billet.

26. The method of claim 20 wherein after heat treating step (D), said tubular-shaped sputtering target is completely recrystallized and strain-free.

27. The method of claim 20 wherein heat treating step (D) is conducted at a temperature of 1250 to 1375° C.

28. The method of claim 20 wherein heat treating step (D) is conducted at a temperature of 815 to 960° C.

29. The method of claim 20 wherein said tubular-shaped sputtering target has an average grain size of less than or equal to 125 μm.

30. The tubular sputtering target prepared by the method of claim 20.

31. A method comprising subjecting the sputtering target of claim 17 to sputtering conditions, thereby sputtering said sputtering target.

32. The method of claim 31 wherein the sputtering is performed using a sputtering method selected from the group consisting of magnetron sputtering, pulse laser sputtering, ion beam sputtering, triode sputtering, and combinations thereof.

33. A method of producing a disc-shaped sputtering target comprising:
(A) (i) placing molybdenum alloy powder in a mold,
(ii) pressing the powder at a pressure of 2.000 bar to 2.500 bar, thereby forming a pressed piece, and
(iii) sintering the pressed piece at a temperature of 1780 to 2175° C. to form a billet having a diameter of Dₒ;
(B) extruding the billet to form an extruded billet having a diameter of D₂, such that the ratio of Dₒ to D₂ is from 3:1 to 5:1;
(C) applying a first heat treatment to the extruded billet at a temperature of 900 to 1300° C., thereby forming a first heat treated extruded billet;
(D) upset forging said first heat treated extruded billet at a temperature of 870 to 1200° C. to form a forged billet having a diameter D_{f}, such that the ratio of D_{f} to D₂ is from 1.5:1 to 3:1; and
(E) applying a second heat treatment to said forged billet at a temperature of 1200 to 1400° C.

34. The method of claim 33 wherein pressing step (A)(i) is performed isostatically.

35. The method of claim 33 wherein sintering step (A)(iii) is conducted in the presence of an inert gas or under a vacuum.

36. The method of claim 33 wherein after second heat treating step (E), said disc-shaped sputtering target is completely recrystallized and strain free.

37. The method of claim 33 further comprising (F) cutting a disc-shaped portion from the heat-treated forged billet to provide said disc-shaped sputtering target.

38. The disk-shaped sputtering target prepared by the method of claim 33.

39. A method comprising subjecting said disk-shaped sputtering target of claim 38 to sputtering conditions, thereby sputtering said disk-shaped sputtering target.

40. The method of claim 39 wherein the sputtering is performed using a sputtering method selected from the group consisting of magnetron sputtering, pulse laser sputtering, ion beam sputtering, triode sputtering and combinations thereof.

41. The disk-shaped sputtering target of claim 38 wherein said disk-shaped sputtering target has an average grain size of less than or equal to 65 μm.
